(19) United States
(12) Patent Application Publication
(10) Pub. No.: US 2018/0246366 A1
(43) Pub. Date: Aug. 30, 2018

(54) DISPLAY PANEL

(71) Applicant: CHUNGHWA PICTURE TUBES, LTD., Taoyuan City (TW)

(72) Inventors: Shiao-Hui LIAO, Miaoli County (TW); Wan-Ting CHANG, Taoyuan City (TW); Chia-Chih HUANG, Taoyuan City (TW); Ya-Tin SU, Taoyuan City (TW); Yueh-Hua HSIEH, Hsinchu County (TW)

(21) Appl. No.: 15/590,015

(22) Filed: May 9, 2017

(30) Foreign Application Priority Data
Feb. 24, 2017 (CN) 201720169684.7

(51) Int. Cl. G02F 1/1333; G02F 1/1335; H01L 27/12; H01L 21/02

(52) U.S. Cl. CPC G02F 1/133345; G02F 1/133512; H01L 21/02107; H01L 27/1214; G02F 1/133514

(57) ABSTRACT

A display panel includes a color filter substrate, a thin film transistor substrate, a first and a second black matrix layers, a colloid, a transparent electrode layer and a conductive adhesive. The first black matrix layer and the second black matrix layer are disposed on a first surface of the color filter substrate. The second black matrix layer is farther away from an edge of the color filter substrate relative to the first black matrix layer. A gap exists between the second and the first black matrix layers. The colloid is aligned with the gap. The transparent electrode layer is disposed on a second surface of the color filter substrate away from the thin film transistor substrate. The conductive adhesive is disposed between the first black matrix layer and the thin film transistor substrate. The conductive adhesive extends towards and contacts with the transparent electrode layer.

### RELATED APPLICATIONS

This application claims priority to Chinese Application Serial Number 201720169684.7, filed Feb. 24, 2017, which is herein incorporated by reference.

### BACKGROUND

### Technical Field

The present disclosure relates to display panels.

### Description of Related Art

With the development of the technology, a variety of electronic products is available on the market. In order to fulfill the increasing demand of people, the quality of the electronic products has to be increasing as well.

Electronic products with a display screen, such as smartphones or tablets, are especially popular for the consumers. Thus, how to increase the display quality provided by the display screen is undoubtedly an important issue in the industry.

### SUMMARY

A technical aspect of the present disclosure is to provide a display panel, which can make it uneasy for the second black matrix layer to be affected by the electrostatic charges from the conductive adhesive, thus effectively enhancing the display effect of the display panel.

According to an embodiment of the present disclosure, a display panel includes a color filter substrate, a thin film transistor substrate, a first black matrix layer, a second black matrix layer, a colloid, a transparent electrode layer and a conductive adhesive. The first black matrix layer is disposed on a first surface of the color filter substrate facing to the thin film transistor substrate. The second black matrix layer is disposed on the first surface. The second black matrix layer is farther away from an edge of the color filter substrate relative to the first black matrix layer. A gap exists between the second black matrix layer and the first black matrix layer. The colloid is disposed between the color filter substrate and the thin film transistor substrate, and the colloid is at least partially aligned with the gap. The transparent electrode layer is disposed on a second surface of the color filter substrate away from the thin film transistor substrate. The conductive adhesive is at least partially disposed between the first black matrix layer and the thin film transistor substrate. The conductive adhesive extends towards the transparent electrode layer and contacts with the transparent electrode layer.

In one or more embodiments of the present disclosure, the conductive adhesive at least partially connects with a third surface of the transparent electrode layer away from the color filter substrate.

In one or more embodiments of the present disclosure, the first black matrix layer has an edge away from the second black matrix layer. The conductive adhesive at least partially covers the edge of the first black matrix layer.

In one or more embodiments of the present disclosure, the conductive adhesive at least partially covers the edge of the color filter substrate away from the second black matrix layer.

In one or more embodiments of the present disclosure, the first black matrix layer has an edge away from the second black matrix layer. The edge of the first black matrix layer and the edge of the color filter substrate away from the second black matrix layer align with each other.

In one or more embodiments of the present disclosure, the display panel further includes an over coat. The over coat is disposed on the first surface and completely covers the first black matrix layer and the second black matrix layer.

In one or more embodiments of the present disclosure, the over coat is at least partially located in the gap.

In one or more embodiments of the present disclosure, the over coat is at least partially located between the first surface and the colloid.

When compared with the prior art, the above-mentioned embodiments of the present disclosure have at least the following advantages:

(1) Because of the isolation by the colloid, the distance between the conductive adhesive and the second black matrix layer is increased. Thus, when the conductive adhesive transmits the electrostatic charges in the transparent electrode layer to the thin film transistor substrate in order to deliver away the electrostatic charges, it becomes uneasy for the conductive adhesive to transmit the electrostatic charges to the second black matrix layer. In addition, since it is uneasy for the second black matrix layer to be affected by the electrostatic charges from the conductive adhesive, the display effect of the display panel is effectively enhanced.

(2) Since the distance between the conductive adhesive and the second black matrix layer is increased, even if the over coat is damaged or defected, it is uneasy for the conductive adhesive to transmit the electrostatic charges to the second black matrix layer through the damaged or defected over coat. Furthermore, since it is uneasy for the second black matrix layer to be affected by the electrostatic charges from the conductive adhesive, the display effect of the display panel is effectively enhanced.

(3) In the manufacturing process of the display panel, during the cutting of the color filter substrate, because of the isolation by the colloid, the cutting line can be restricted on the first black matrix layer. Therefore, the chance that the second black matrix layer to be cut during the manufacturing process to connect the conductive adhesive is effectively reduced. In this way, the display quality of the display panel is also protected.

### BRIEF DESCRIPTION OF THE DRAWINGS

The disclosure can be more fully understood by reading the following detailed description of the embodiments, with reference made to the accompanying drawings as follows:

FIG. 1 is a sectional schematic view of a display panel according to an embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

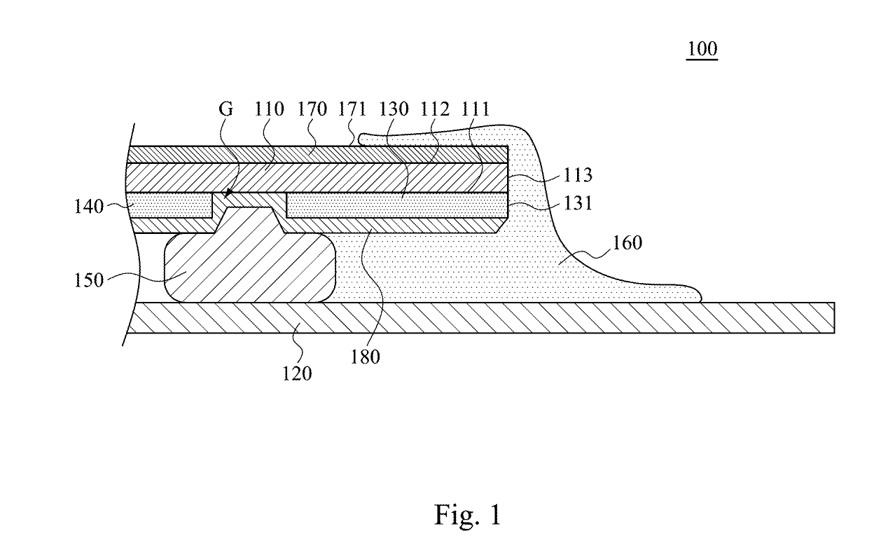

Please refer to FIG. 1. FIG. 1 is a sectional schematic view of a display panel 100 according to an embodiment of the present disclosure. As shown in FIG. 1, a display panel 100 includes a color filter (CF) substrate 110, a thin film transistor (TFT) substrate 120, a first black matrix (BM) layer 130, a second black matrix layer 140, a colloid 150, a transparent electrode layer 170 and a conductive adhesive 160. In practical applications, the color filter substrate 110 can substantially be a color filter glass substrate, while the thin film transistor substrate 120 can substantially be a thin film transistor glass substrate. However, these options do not intend to limit the present disclosure. The first black matrix layer 130 is disposed on a first surface 111 of the color filter substrate 110 facing to the thin film transistor substrate 120. The second black matrix layer 140 is disposed on the first surface 111. The second black matrix layer 140 is farther away from an edge 113 of the color filter substrate 110 relative to the first black matrix layer 130. A gap G exists between the second black matrix layer 140 and the first black matrix layer 130. In this embodiment, the first black matrix layer 130 is the outer black matrix layer near to the edge region of the display panel 100, while the second black matrix layer 140 is the inner black matrix layer near to the central region of the display panel 100. In fact, the colloid 150 is a part of a sealant (not shown). The sealant is a frame structure in this industry, which is disposed between the color filter substrate 110 and the thin film transistor substrate 120. The sealant is not described in details here. The colloid 150 is disposed between the color filter substrate 110 and the thin film transistor substrate 120, and the colloid 150 is at least partially aligned with the gap G. In this embodiment, as shown in FIG. 1, a central part of the colloid 150 is aligned with the gap G. However, this does not intend to limit the present disclosure. The transparent electrode layer 170 is disposed on a second surface 112 of the color filter substrate 110 away from the thin film transistor substrate 120. The second surface 112 is disposed opposite to the first surface 111. The conductive adhesive 160 is at least partially disposed between the first black matrix layer 130 and the thin film transistor substrate 120, and is connected with a side of the colloid 150 near to the first black matrix layer 130 (i.e., the side of the colloid 150 away from the second black matrix layer 140). In addition, the conductive adhesive 160 extends towards the transparent electrode layer 170 and contacts with the transparent electrode layer 170. Furthermore, the conductive adhesive 160 is electrically grounded through the thin film transistor substrate 120. In practical applications, the conductive adhesive 160 can be sliver conductive adhesive. However, this does not intend to limit the present disclosure.

In this way, because of the isolation by the colloid 150, the distance between the conductive adhesive 160 and the second black matrix layer 140 is increased. Thus, when the conductive adhesive 160 transmits the electrostatic charges in the transparent electrode layer 170 to the thin film transistor substrate 120 in order to deliver away the electrostatic charges, it becomes uneasy for the conductive adhesive 160 to transmit the electrostatic charges to the second black matrix layer 140. In addition, since it is uneasy for the second black matrix layer 140 to be affected by the electrostatic charges from the conductive adhesive 160, the display effect of the display panel 100 is effectively enhanced. In practical applications, the transparent electrode layer 170 can include indium tin oxide (ITO). However, this does not intend to limit the present disclosure.

Furthermore, in the manufacturing process of the display panel 100, during the cutting of the color filter substrate 110, because of the isolation by the colloid 150, the cutting line can be restricted on the first black matrix layer 130. Therefore, the chance that the second black matrix layer 140 to be cut during the manufacturing process to connect the conductive adhesive 160 is effectively reduced. In this way, the display quality of the display panel 100 is also protected.

On the other hand, structurally speaking, the first black matrix layer 130 has an edge 131 away from the second black matrix layer 140. The conductive adhesive 160 at least partially covers the edge 131. Moreover, the color filter substrate 110 has the edge 113 away from the second black matrix layer 140. Similarly, the conductive adhesive 160 at least partially covers the edge 113. This means, the conductive adhesive 160 is at least partially located outside the range between the first black matrix layer 130 and the thin film transistor substrate 120.

In practical applications, the conductive adhesive 160 extends towards the transparent electrode layer 170 along the edge 131 of the first black matrix layer 130 and the edge 113 of the color filter substrate 110. In addition, the conductive adhesive 160 covers and connects with the edge 131 of the first black matrix layer 130, and covers and connects with the edge 113 of the color filter substrate 110, so as to at least partially connect with a third surface 171 of the transparent electrode layer 170 away from the color filter substrate 110 in order to deliver away the electrostatic charges in the transparent electrode layer 170. Thus, the display effect of the display panel 100 is enhanced.

To be more specific, in practical applications, in order to make closer the structure of the conductive adhesive 160 covering and connecting with the edge 131 of the first black matrix layer 130, and covering and connecting with the edge 113 of the color filter substrate 110, the edge 131 of the first black matrix layer 130 and the edge 113 of the color filter substrate 110 are aligned with each other.

In practical applications, the display panel 100 further includes an over coat (OC) 180. As shown in FIG. 1, the over coat 180 is disposed on the first surface 111 of the color filter substrate 110, and completely covers the first black matrix layer 130 and the second black matrix layer 140. In other words, the first black matrix layer 130 and the second black matrix layer 140 are respectively located between the first surface 111 of the color filter substrate 110 and the over coat 180. This means both the first black matrix layer 130 and the second black matrix layer 140 are covered and protected by the over coat 180. To be more specific, the over coat 180 further covers the first surface 111 located within the gap G. This means the over coat 180 is at least partially located between the first surface 111 of the color filter substrate 110 and the colloid 150.

As mentioned above, since the distance between the conductive adhesive 160 and the second black matrix layer 140 is increased, even if the over coat 180 is damaged or defected, it is uneasy for the conductive adhesive 160 to transmit the electrostatic charges to the second black matrix layer 140 through the damaged or defected over coat 180. Furthermore, since it is uneasy for the second black matrix layer 140 to be affected by the electrostatic charges from the conductive adhesive 160, the display effect of the display panel 100 is effectively enhanced.

In summary, when compared with the prior art, the embodiments of the present disclosure mentioned above have at least the following advantages:

(1) Because of the isolation by the colloid, the distance between the conductive adhesive and the second black matrix layer is increased. Thus, when the conductive adhesive transmits the electrostatic charges in the transparent electrode layer to the thin film transistor substrate in order to deliver away the electrostatic charges, it becomes uneasy for the conductive adhesive to transmit the electrostatic charges to the second black matrix layer. In addition, since it is uneasy for the second black matrix layer to be affected by the electrostatic charges from the conductive adhesive, the display effect of the display panel is effectively enhanced.

(2) Since the distance between the conductive adhesive and the second black matrix layer is increased, even if the over coat is damaged or defected, it is uneasy for the conductive adhesive to transmit the electrostatic charges to the second black matrix layer through the damaged or defected over coat. Furthermore, since it is uneasy for the second black matrix layer to be affected by the electrostatic charges from the conductive adhesive, the display effect of the display panel is effectively enhanced.

(3) In the manufacturing process of the display panel, during the cutting of the color filter substrate, because of the isolation by the colloid, the cutting line can be restricted on the first black matrix layer. Therefore, the chance that the second black matrix layer to be cut during the manufacturing process to connect the conductive adhesive is effectively reduced. In this way, the display quality of the display panel is also protected.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A display panel, comprising:
a color filter substrate;
a thin film transistor substrate;
a first black matrix layer disposed on a first surface of the color filter substrate facing to the thin film transistor substrate;
a second black matrix layer disposed on the first surface, the second black matrix layer being farther away from an edge of the color filter substrate relative to the first black matrix layer, a gap existing between the second black matrix layer and the first black matrix layer;
a colloid disposed between the color filter substrate and the thin film transistor substrate, and at least partially aligned with the gap;
a transparent electrode layer disposed on a second surface of the color filter substrate away from the thin film transistor substrate; and
a conductive adhesive at least partially disposed between the first black matrix layer and the thin film transistor substrate, the conductive adhesive extending towards the transparent electrode layer and contacting with the transparent electrode layer.

2. The display panel of claim 1, wherein the conductive adhesive at least partially connects with a third surface of the transparent electrode layer away from the color filter substrate.

3. The display panel of claim 1, wherein the first black matrix layer has an edge away from the second black matrix layer, the conductive adhesive at least partially covers the edge of the first black matrix layer.

4. The display panel claim 1, wherein the conductive adhesive at least partially covers the edge of the color filter substrate away from the second black matrix layer.

5. The display panel of claim 1, wherein the first black matrix layer has an edge away from the second black matrix layer, the edge of the first black matrix layer and the edge of the color filter substrate away from the second black matrix layer align with each other.

6. The display panel of claim 1, further comprising:
an over coat disposed on the first surface and completely covering the first black matrix layer and the second black matrix layer.

7. The display panel of claim 6, wherein the over coat is at least partially located in the gap.

8. The display panel of claim 6, wherein the over coat is at least partially located between the first surface and the colloid.
